(19) United States
(12) Patent Application Publication
(10) Pub. No.: US 2005/0116258 A1
(43) Pub. Date: Jun. 2, 2005

(54) Two-modulus prescaler circuit

(76) Inventors: Akihiro Yamagishi, Kanagawa (JP); Tsuneo Tsukahara, Kanagawa (JP); Yukio Shimpo, Kanagawa (JP)

Correspondence Address: JOHN S. PRATT, ESQ;KILPATRICK STOCKTON, LLP, 1100 PEACHTREE STREET, ATLANTA, GA, 30309, US

(21) Appl. No.: 10/499,640

(22) PCT Filed: Dec. 17, 2002
(86) PCT No.: PCT/JP02/13190

(30) Foreign Application Priority Data
Dec. 20, 2001 (JP) 2001-386873

(51) Int. Cl. H01L 29/768

(52) U.S. Cl. 257/222

(57) ABSTRACT

In the dual modulus prescaler circuit, an output terminal of the first multi-input logic gate circuit is connected to a data input terminal of a first D flip-flop circuit; output terminals of the first to (n-2)th D flip-flop circuits are, respectively, connected to data input terminals of the second to (n-1)th D flip-flop circuits; output terminals of the (n-1)th and nth D flip-flop circuits are connected to input terminals of the first multi-input logic gate circuit; the second multi-input logic gate circuit is connected to the output terminal of the (n-1)th D flip-flop circuit and receives a switching signal; and an output terminal of the second multi-input logic gate circuit is connected to a data input terminal of the nth D flip-flop circuit. Moreover, all the aforementioned connections are connections using differential signals.

### TECHNICAL FIELD

The present invention relates to a dual modulus prescaler circuit applicable to frequency synthesizers and the like. Specifically, the present invention relates to a dual modulus prescaler circuit which can operate with small signal amplitude and with reduced power consumption.

### BACKGROUND OF THE INVENTION

A “divide-by 4/divide-by 5 divider” switchable between divide-by 4 and divide-by 5 modes, which is a basis for a dual modulus prescaler used for a pulse swallow type PLL synthesizer, is composed of a circuit as shown in FIG. 1. In FIG. 1, reference numerals 11 to 13 denote D flip-flop circuits (DFF circuits), and reference numerals 14 and 15 denote NOR circuits. This circuit is configured to switch between divide-by 4 and divide-by 5 modes by means of a polarity of an input signal of a terminal M.

FIG. 2 is a timing chart showing an operation of the “divide-by 4/divide-by 5 divider”. As shown in FIG. 2, in the “divide-by 4/divide-by 5 divider”, when an input of the terminal M is H1, an input D of the DFF3 remains unchanged, and the input signal is frequency-divided by four with the DFF1 and DFF2. On the contrary, when the input of the terminal M is Low, the DFF3 operates, and the input signal is frequency-divided by five.

Further, by adding a frequency divider to the output of the circuit, a dual modulus prescaler circuit switchable between divide-by 2n and divide-by 2n+1 modes can be configured. FIG. 3 is a block diagram of a “divide-by 32/divide-by 33 divider” using the “divide-by 4/divide-by 5 divider”. Reference numerals 11 to 13 denote D flip-flop circuits (DFF circuits); 14 and 15. NOR circuits; 16, an OR circuit; and 21 to 23, T flip-flop circuits (TFF circuits).

In the circuit of FIG. 3, each of the DFF1, DFF2, and DFF3 constituting the “divide-by 4/divide-by 5 divider” is required to operate at a frequency of an input signal. The TFF1, TFF2, and TFF3 which receive divided signals operate at a lower frequency as they get closer to the last stage.

Therefore, in order to reduce the power consumption of the dual modulus prescaler, it is important to reduce the power consumption of the “divide-by 4/divide-by 5 divider”. Generally, prescalers require high-speed operation, and so bipolar processes are often used. However, CMOS prescalers have been developed along with achieving higher speed CMOS processes in recent years.

In the case of CMOS processes, it is possible to conceive a DFF circuit using a current mode logic circuit as shown in FIG. 4, which can be expected to offer faster performance than that using normal CMOS gates. The circuit of FIG. 4 includes a master FF and a slave FF. The master FF is composed of transistors M1 to M6 and R1 and R2, and the slave FF is composed of M8 to M13, R3, and R4. I-1 and I-2 of FIG. 4 denote current sources.

The transistors M5 and M6 and the transistors M12 and M13 are turned on and off by a clock inputted as a differential signal to switch current paths. When CN is Hi and CP is Low, the current path is through the M5 side in the master FF. At this time, if a gate voltage IN of M1 is higher than a gate voltage IP of M2, current flows through R1, and Low is read. If IN is lower than IP, current flows through R2, and H1 is read. Simultaneously, the current path Is through the M13 side in the slave FF, and an output is held by M10 and M11.

When CN is Low and CP is Hi, the current path is through the M6 side in the master FF, and data is held by M3 and M4. The current path is through the M12 side in the slave FF, and data is outputted through M8 and M9. This circuit operates as a DFF circuit according to the aforementioned operations.

The NOR circuit used in the “divide-by 4/divide-by 5 divider” can be easily implemented only by replacing the transistor M1 for data input in the DFF circuit of FIG. 4 with transistors M1A and M1B connected to each other in parallel as shown in FIG. 5. Signals and the like in FIG. 5 are the same as those in FIG. 4.

In the DFF circuit with a NOR gate shown in FIG. 5, in reading data when CP is Low, if any one of a gate voltage A of M1A and a gate voltage B of M1B or both thereof are higher than a gate voltage VR of M2, current flows through R1, and Low is read. When both of A and B are lower than VR, current flows through R2, and Hi is read. Therefore, this circuit operates as a DFF circuit with a NOR gate.

The DFF circuit with a NOR gate shown in FIG. 5 requires a threshold voltage VR for judging whether data is Low or Hi since single-phase data is inputted. Power supply voltage necessary for operating this circuit requires being a voltage value obtained by adding signal amplitude to operating voltages of individual transistors. The DFF circuit with a NOR gate of FIG. 5 requires a total voltage of a voltage for operating three transistors and signal amplitude.

Larger signal amplitude provides larger operating margins but requires larger power supply voltage. The DFF circuit with a NOR gate of FIG. 5 requires larger signal amplitude to ensure a DC bias operating margin since single-phase data is inputted. Therefore, it is difficult to reduce the power supply voltage.

### SUMMARY OF THE INVENTION

The present invention according to the application was made to solve the aforementioned problem. Specifically, an aspect of the present invention according to claim 1 is a dual modulus prescaler circuit for dividing an inputted clock signal to obtain a divide ratio which is selected by a switching signal from a combination of predetermined divide ratios. The dual modulus prescaler circuit includes: n D flip-flop circuits, n being a natural number not less than three; a first multi-input logic gate circuit including at least two input terminals; and a second multi-input logic gate circuit including at least two input terminals. An output terminal of the first multi-input logic gate circuit is connected to a data input terminal of the first D flip-flop circuit; output terminals of the first to (n-2)th D flip-flop circuits are connected to data input terminals of the second to (n-1)th D flip-flop circuits; output terminals of the (n-1)th and nth D flip-flop circuits are connected to input terminals of the first multi-input logic gate circuit; the second multi-input logic gate circuit is connected to the output terminal of the (n-1)th D flip-flop circuit and receives the switching signal, and an output terminal of the second multi-input logic gate circuit is connected to the data input terminal of the nth D flip-flop circuit. Moreover, all the aforementioned connections are connections using differential signals.

Another aspect of the present invention according to claim 2 is the dual modulus prescaler circuit according to claim 1, in which a multi-input logic gate circuit is used for each of the first and second multi-input logic gate circuits, the multi-input logic gate circuit including a current source, first and second resistors each of which has an end connected to a power supply, m transistors connected in parallel, whose sources are connected to an output end of the current source and whose drains are connected to the other end of the first resistor, and further m transistors connected in series, whose sources and drains are connected between the output end of the current source and the other end of the second resistor. Herein, m is a natural number not less than two. Moreover, m differential input data are applied between gates of the transistors connected in parallel and gates of the transistors connected in series, and a differential signal is obtained as an output of the multi-input logic gate circuit at the other ends of the first and second resistors.

A still another aspect of the present invention according to claim 3 is the dual modulus prescaler according to claim 1, in which a D flip-flop circuit with a logic gate circuit is used for each of combinations of the first multi-input logic gate circuit and the first D flip-flop circuit and of the second multi-input logic gate circuit and the nth D flip-flop circuit, the logic gate circuit including: first and second current sources; first and second transistors whose sources are connected to an output end of the first current source; third and fourth transistors whose sources are connected to an output end of the second current source; fifth, sixth, and seventh transistors whose sources are connected to a drain of the first transistor; an eighth transistor whose source is connected to a drain of the seventh transistor; ninth and tenth transistors whose sources are connected to a drain of the second transistor; eleventh and twelfth transistors whose sources are connected to a drain of the third transistor; thirteenth and fourteenth transistors whose sources are connected to a drain of the fourth transistor; a first resistor whose terminal is connected to a power supply and whose other terminal is connected to drains of the fifth, sixth, and ninth transistors and to gates of the tenth and eleventh transistors; a second resistor whose terminal is connected to the power supply and whose other terminal is connected to drains of the eighth and tenth transistors and to gates of the ninth and twelfth transistors; a third resistor whose terminal is connected to the power supply and whose other terminal is connected to drains of the eleventh and thirteenth transistors and to a gate of the fourteenth transistor; and a fourth resistor whose terminal is connected to the power supply and whose other terminal is connected to drains of the twelfth and fourteenth transistors and to a gate of the thirteenth transistor. Moreover, differential clock signals are applied between gates of the first and fourth transistors and between gates of the second and third transistors; a first differential data is applied between gates of the fifth and eighth transistors; and a second differential data is applied between gates of the sixth and seventh transistors.

Still another aspect of the present invention according to claim 4 is the dual modulus prescaler circuit according to claim 3, in which, in the D flip-flop circuit with a logic gate circuit, the current sources are eliminated, and the sources of the first, second, third, and fourth transistors are connected to the ground.

In the present invention, as described above, the DFF circuit with a NOR gate is configured to receive differential inputs, so that the signal amplitude can be reduced. The use of differential signals allows the signal amplitude to be reduced to half, thus achieving reduced power supply voltage. Therefore, there are a method for constituting the DFF circuit with a NOR gate by use of a differential input/differential output NOR/OR circuit and a differential DFF circuit and a method for using a differential input DFF circuit with a NOR gate.

### BRIEF DESCRIPTION OF THE DRAWINGS

FIG. 1 is a view showing a configuration of a conventional “divide-by 4/divide-by 5 divider”.

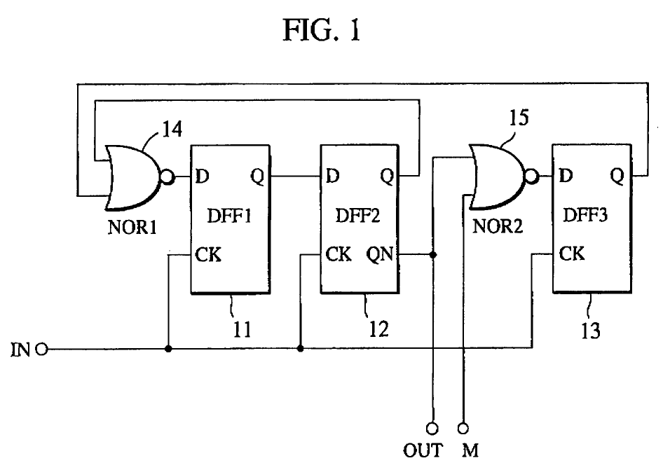

FIG. 2 is a view showing a timing chart of the conventional “divide-by 4/divide-by 5 dividers”.

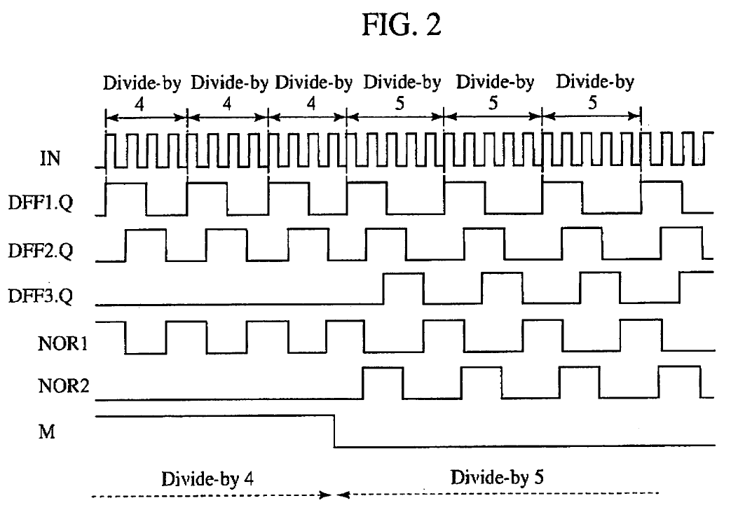

FIG. 3 is a view showing a configuration of a conventional “divide-by 32/divide-by 33 divider”.

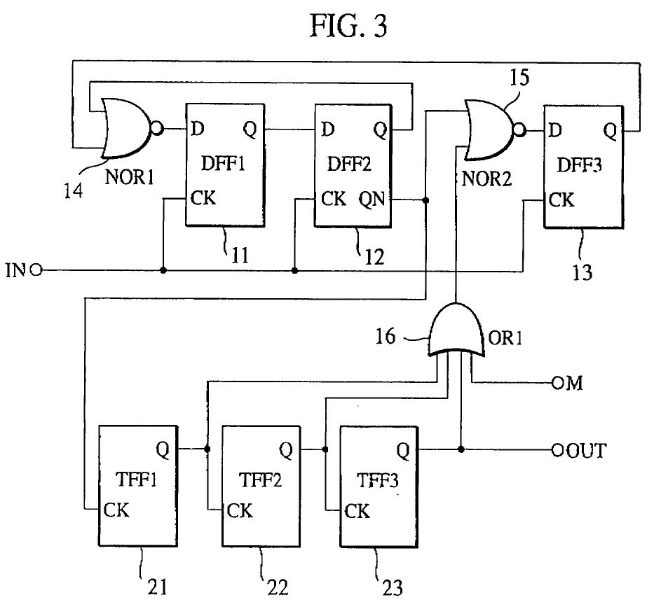

FIG. 4 is a view showing a configuration of a conventional DFF circuit.

FIG. 5 is a view showing a configuration of a conventional DFF circuit with a NOR gate.

FIG. 6 is a view showing a configuration of a circuit according to a first embodiment.

FIG. 7 is a view showing a configuration of a differential input/output NOR circuit according to the first embodiment.

FIG. 8 is a view showing a configuration of a DFF circuit with a NOR gate according to a second embodiment.

### DETAIL DESCRIPTION OF THE INVENTION

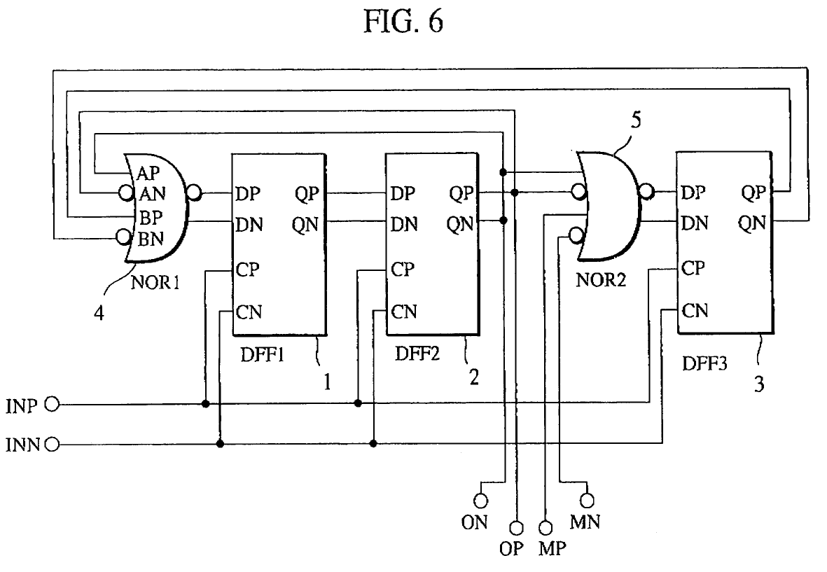

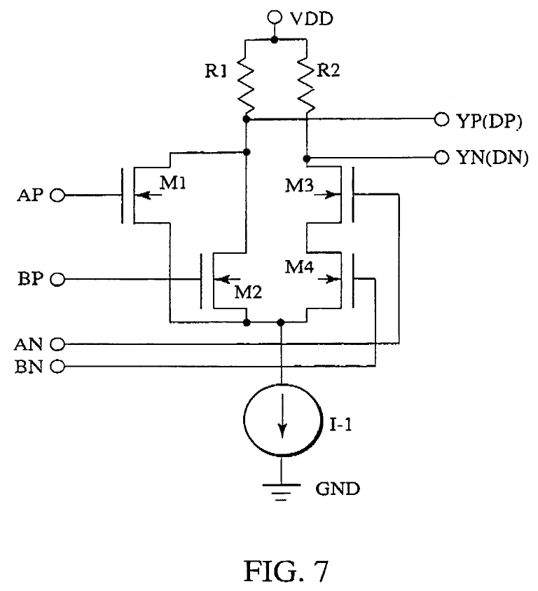

FIG. 6 is a view showing a first embodiment of the present invention. This embodiment corresponds to an aspect of the present invention according to claim 1. In the drawing, reference numerals 1 to 3 denote DFF circuits, and 4 and 5 denote NOR circuits. The circuit of FIG. 6 is configured so that differential signals are inputted to/outputted from all the DFF circuits (D flip-flop circuits) and NOR circuits (multi-input logical gate circuits). An example of the differential input/output NOR circuit is shown in FIG. 7. This circuit corresponds to a NOR circuit defined by another aspect of the present invention according to claim 2.

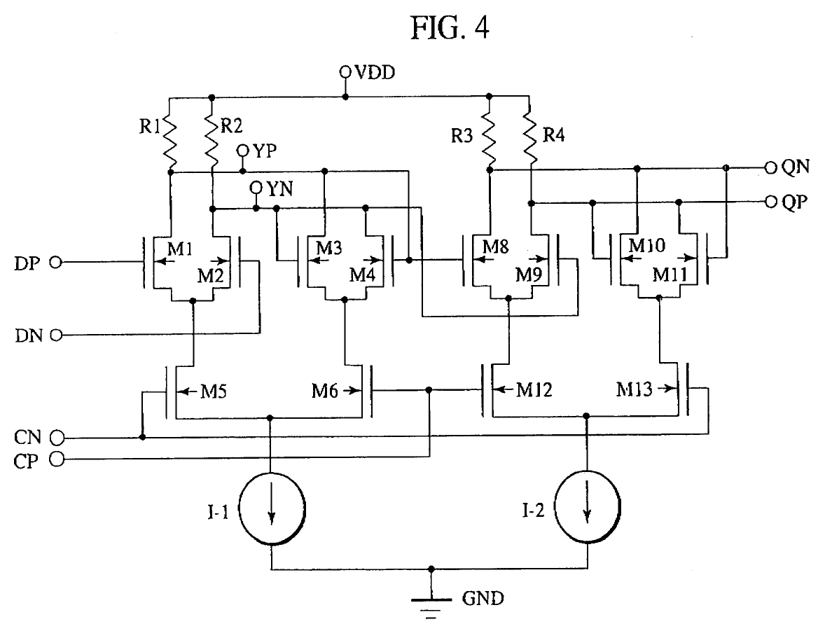

The circuit of FIG. 7 is a NOR circuit operated in a current mode in order to ensure high speed performance. In FIG. 7, R1 and R2 denote resistors: M1 to M4, transistors; I-1, a current source; AP, an input signal; and YP, an output signal. When the terminals AP and BP in the circuit of FIG. 7 are Hi, AN and BN are Low. At this time, current flows through R1 but does not flow through R2. Accordingly, YP is Low, and YN is Hi. When AP is Hi and BP is Low or when YP is Low and BP is Hi, current flows through R1. Accordingly, YP is Low, and YN is Hi. In other words, YP acts as the NOR to AP and BP. Herein, the aforementioned circuit of FIG. 4 is used for each of the DFF circuits.

The circuit of FIG. 4 includes a master FF and a slave FF. The master FF is composed of transistors M1 to M6 and R1 and R2, and the slave FF is composed of M8 to M13 and R3 and R4. The transistors M5 and M6 and the transistors M12 and M13 are turned on and off by a clock inputted as a differential signal to switch current paths.

When CN is Hi and CP is Low, the current path is through the M5 side in the master FF. At this time, if a gate voltage IN of M1 is higher than a gate voltage IP of M2, current flows through R1, and Low is read. If IN is lower than IP, current flows through R2, and Hi is read. Simultaneously, the current path in the slave FF is through the M13 side, and the output is held by M10 and M11.

When CN is Low and CP is Hi, the current path is through the M6 side in the master FF, and data is held by M3 and M4. In the slave FF, the current path is through the M12 side, and data is outputted through M8 and M9. This circuit operates as a DFF circuit according to the aforementioned operations. A fully differential “divide-by 4/divide-by 5 divider” can be implemented by using the circuit of FIG. 7 for each NOR circuit and using the circuit of FIG. 4 for each DFF circuit.

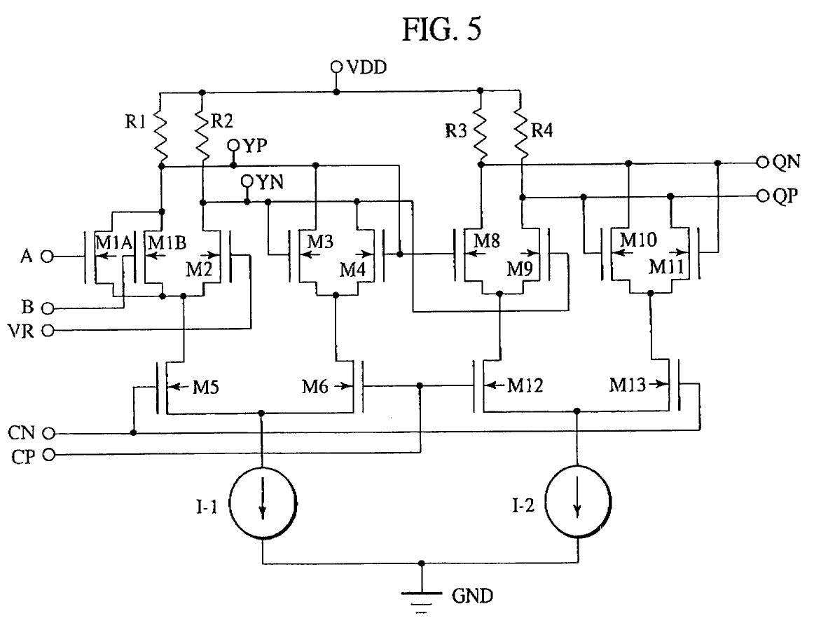

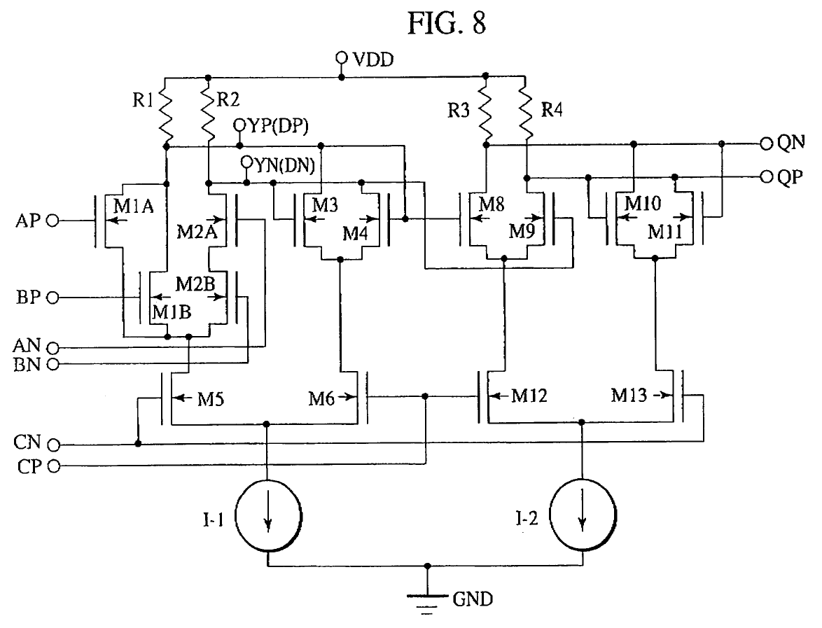

FIG. 8 is a view showing a second embodiment of the present invention, corresponding to still another aspect of the invention according to claim 3. The circuit of FIG. 8 is a circuit in which the transistor M2 of the DFF circuit with a NOR gate shown in FIG. 5 is replaced with transistors M2A and M2B which are connected in series. In the circuit of FIG. 8, differential signals are applied between AP and AN and between BP and BN.

In reading data when CP is Low, only in the case where AP and BP are Low, AN and BN are Hi, and current flows through R2. Accordingly, Hi is read. In other cases, current flows through any one or both of M1A and M1B, and any one or both of M2A and M2B are turned off. Accordingly, current flows through R1, and Low is read.

Therefore, the circuit of FIG. 8 operates as the DFF circuit with a NOR gate. It is possible to implement the fully differential “divide-by 4/divide-by 5 divider” by applying the DFF circuit with a NOR gate of FIG. 8 to each of combinations of NOR1 and DFF1 and of NOR2 and DFF 3 in FIG. 6 and applying the DFF circuit of FIG. 4 to DFF2. Moreover, the DFF circuit with a NOR gate of FIG. 8 and the DFF circuit of FIG. 4 can operate even when the current sources are omitted since the clock signals thereof are differential. Accordingly, the power supply voltage can be further lowered by omitting the current sources.

Industrial Applicability

According to the present invention, all the circuits constituting the dual modulus prescaler are designed to be differential input and/or differential output circuits. Accordingly, compared to conventional circuits operating margins for signal amplitude and a signal direct current level can be increased, so that the dual modulus prescaler can operate with smaller signal amplitude. This offers advantages of reducing power supply voltage and power consumption.

1. A dual modulus prescaler circuit for dividing an inputted clock signal to obtain a divide ratio which is selected by a switching signal from a combination of predetermined divide ratios, the dual modulus prescaler circuit comprising:
n D flip-flop circuits, n being a natural number not less than three;
a first multi-input logic gate circuit including at least two inputs: and
a second multi-input logic gate circuit including at least two inputs, wherein
an output terminal of the first multi-input logic gate circuit is connected to a data input terminal of the first D flip-flop circuit,
output terminals of the first to (n-2)th D flip-flop circuits are connected to data input terminals of the second to (n-1)th D flip-flop circuits,
output terminals of the (n-1)th and nth D flip-flop circuits are connected to input terminals of the first multi-input logic gate circuit,
the second multi-input logic gate circuit is connected to the output terminal of the (n-1)th D flip-flop circuit and includes a terminal to which the switching signal is inputted, and
an output terminal of the second multi-input logic gate circuit is connected to a data input terminal of the nth D flip-flop circuit, and wherein
all the connections are connections using differential signals.

2. The dual modulus prescaler circuit according to claim 1, wherein a multi-input logic gate circuit is used for each of the first and second multi-input logic gate circuits, the multi-input logic gate circuit including a current source, first and second resistors each of which has an end connected to a power supply, m transistors connected in parallel, m being a natural number not less than two, whose sources are connected to an output end of the current source and whose drains are connected to the other end of the first resistor and further m transistors connected in series, whose sources and drains are connected between the output end of the current source and the other end of the second resistor, wherein
m differential input data are applied between gates of the transistors connected in parallel and gates of the transistors connected in series, and wherein
a differential signal is obtained as an output of the multi-input logic gate circuit at the other ends of the first and second resistors.

3. The dual modulus prescaler according to claim 1, wherein a D flip-flop circuit with a logic gate circuit is used for each of combinations of the first multi-input logic gate circuit and the first D flip-flop circuit and of the second multi-input logic gate circuit and the nth D flip-flop circuit, the logic gate circuit including:
first and second current sources;
first and second transistors whose sources are connected to an output end of the first current source;
third and fourth transistors whose sources are connected to an output end of the second current source;
fifth, sixth, and seventh transistors whose sources are connected to a drain of the first transistor;
an eighth transistor whose source is connected to a drain of the seventh transistor;
ninth and tenth transistors whose sources are connected to a drain of the second transistor;
eleventh and twelfth transistors whose sources are connected to a drain of the third transistor;
thirteenth and fourteenth transistors whose sources are connected to a drain of the fourth transistor;
a first resistor whose terminal is connected to a power supply and whose other terminal is connected to drains of the fifth, sixth, and ninth transistors and to gates of the tenth and eleventh transistors;
a second resistor whose terminal is connected to the power supply and whose other terminal is connected to drains of the eighth and tenth transistors and to gates of the ninth and twelfth transistors;
a third resistor whose terminal is connected to the power supply and whose other terminal is connected to drains of the eleventh and thirteenth transistors and to a gate of the fourteenth transistor; and
a fourth resistor whose terminal is connected to the power supply and whose other terminal is connected to drains of the twelfth and fourteenth transistors and to a gate of the thirteenth transistor, and wherein
differential clock signals are applied between gates of the first and fourth transistors and between gates of the second and third transistors;
a first differential data is applied between gates of the fifth and eighth transistors; and
a second differential data is applied between gates of the sixth and seventh transistors.

4. The dual modulus prescaler circuit according to claim 3, wherein, in the D flip-flop circuit with a logic gate circuit, the current sources are eliminated, and the sources of the first, second, third, and fourth transistors are connected to the ground.
